(19) United States
(12) Patent Application Publication
(10) Pub. No.: US 2013/0258573 A1
(43) Pub. Date: Oct. 3, 2013

(54) COVER FOR ELECTRONIC TOUCHSCREEN DEVICE

(71) Applicants: Thomas P. Muday, Scottsdale, AZ (US); Christopher M. Stalzer, Scottsdale, AZ (US)

(72) Inventors: Thomas P. Muday, Scottsdale, AZ (US); Christopher M. Stalzer, Scottsdale, AZ (US)

(21) Appl. No.: 13/852,967

(22) Filed: Mar. 28, 2013

Related U.S. Application Data
(60) Provisional application No. 61/616,896, filed on Mar. 28, 2012.

(51) Int. Cl. G06F 1/16; H05K 5/06; H05K 5/02; H05K 5/00

(52) U.S. Cl. CPC G06F 1/1613; H05K 5/0017; H05K 5/06; H05K 5/0217; H05K 5/0247
USPC 361/679.21; 361/679.01

(57) ABSTRACT

A cover for an electronic touchscreen device is provided. The cover includes a coupling member and a device housing, which secures therein the electronic touchscreen device. The coupling member includes a front plate that is releasably coupled to the device housing. The coupling member further includes a coupling body that releasably couples the cover to a user's vest, backpack, or other portable item. The front plate and the coupling body are configured to move with respect to one another to transition the cover between closed and open positions. The device housing further includes a housing lid and a housing body. The housing lid and housing body cooperate to secure therebetween the touchscreen device. The user operates the touchscreen device through the housing lid and conductive components thereof under the condition that the cover is in the open position. The device is protected in the closed position.

### CROSS REFERENCE TO RELATED APPLICATION[S]

This application claims priority to U.S. Provisional Patent Application to Muday, et al., entitled “COVER FOR ELECTRONIC TOUCHSCREEN DEVICE,” Ser. No. 61/616,896, filed Mar. 28, 2012, the disclosure of which is hereby incorporated entirely herein by reference.

### BACKGROUND

1. Technical Field

The following relates to a communication system for electronic devices, and in particular to a high-end communication system and cover for touchscreen electronic devices.

2. State of the Art

Communication is the activity of conveying information. Communication generally requires a sender, a message, and an intended recipient. Communication can occur in close proximity or across vast distances in time and space. Communication requires that the communicating parties share an area of communicative commonality. Wireless communication, the internet, and personal electronic devices, such as cell phones, smart phones, and tablets, have enabled senders and recipients to communicate almost immediately with one another and to do so with relative ease.

Different environments and situations require different means of communication. Some situations require communication to be quick and short while others permit communication to be deliberate and drawn-out. Some situations, such as tactical operations and environments, require communication to be efficient, secure, precise, and reliable. Tactical operators must be able to rely on their communication means to facilitate exact and coordinated movements of personnel, gear, and/or equipment. Also, tactical environments require communication means that can withstand the rigors of the operation. Tactical environments further require that the means of communication serve to allow the tactical operator to receive and send vital operational instructions, messages, directions, objectives, status, and feedback to one another or to a central control unit. However, such communication should not distract the tactical operator from focusing on or accomplishing the task at hand.

Personal electronic devices, such as cell phones, smart phones, tablets, and personal computers can be used by each tactical operator to perform the communication tasks required by the operation. However, use of any communication means that are not designed to address the needs of the operator may pose problems, such as those described above, to the individual operator.

Accordingly, there is a need in the tactical industry for a cover that functions with various personal electronic devices to facilitate the tactical operator's repeated, efficient, reliable and safe use of these personal electronic devices to communicate with others.

### SUMMARY

The following relates to a communication system for electronic devices, and in particular to a high-end communication system and cover for touchscreen electronic devices.

A first general aspect relates to the system including a coupling member and a device housing, which secures therein the electronic touchscreen device. The coupling member includes a front plate that is releasably coupled to the device housing. The coupling member further includes a coupling body that releasably and functionally couples the device housing to a user's vest, backpack, or other portable item. The front plate and the coupling body are configured to move with respect to one another to transition the device housing between closed and open positions, or first and second positions. The device housing further includes a housing lid and a housing body. The housing lid and housing body cooperate to secure therebetween the touchscreen device. The user operates the touchscreen device through the housing lid and conductive components thereof under the condition that the system is in the open position. The device is protected in the closed position.

Another general aspect relates to a communication system for an electronic device, the system comprising a device housing having a housing body with a transparent surface, the housing body defining a cavity, the cavity being configured to house the electronic device therein such that a touchscreen of the electronic device is visible through the transparent surface, a coupling member having a coupling plate and a coupling body, the coupling plate being configured to releasably couple to the housing body, the coupling plate and the coupling body being configured to pivot with respect to one another between a first position and a second position, and a communication port coupled to the housing body and configured to place the electronic device in electrical communication with an external electronic device, wherein in the closed position the transparent surface is proximate the coupling body and in the open position the touchscreen is accessible.

Another general aspect relates to wherein the device housing further comprises a housing lid that is configured to pivot between an open position and a closed position, wherein in the open position the housing lid provides access to the cavity and in the closed position the housing lid is configured to close the cavity.

Another general aspect relates to a retaining member configured to functionally engage the coupling plate to retain the coupling plate and the coupling body in the closed position. The retaining member may be configured to releasably couple to a user. The retaining member may further comprise a plurality of prongs that are configured to releasably couple to PALS webbing in a MOLLE system worn by the user.

Another general aspect relates to wherein the coupling body is configured to releasably couple to a user, and wherein the coupling body further comprises a plurality of prongs that are configured to releasably couple to PALS webbing in a MOLLE system worn by the user.

Another general aspect relates to wherein the communication port further comprises a USB plug housed within a shield member, wherein the shield member is configured to shield the USB plug from EMI, and wherein the USB plug operatively engages the electronic device to establish connection between the electronic device and the external electronic device via a cable.

Another general aspect relates to wherein the external electronic device is a power source or a computer.

Another general aspect relates to a protective cover for an electronic device, the protective cover comprising a housing body defining a cavity therein, a transparent screen coupled to the housing body, the transparent screen providing visibility into the cavity, a housing lid in functional communication with the housing body to provide access to the cavity and to seal the cavity; and a communication port configured to place the electronic device in electrical communication with an external electronic device via a cable.

Another general aspect relates to wherein the cavity is configured to house the electronic device, and wherein under the condition the electronic device is in the cavity a touchscreen display of the electronic device is visible through the transparent screen.

Another general aspect relates to wherein the transparent screen is capacitive and a user may operate the touchscreen display of the electronic device through the transparent screen.

Another general aspect relates to wherein the housing body has a rigid unitary construction and under the condition the housing lid functionally engages the housing body, the cavity is hermetically sealed.

Another general aspect relates to wherein the communication port is a USB plug that operatively engages a corresponding USB port of the electronic device within the cavity.

Another general aspect relates to wherein the communication port further comprises a shield member, the shield member comprising metal and being configured to enclose the USB plug to shield the USB plug from EMI.

Another general aspect relates to wherein the shield member further comprises foam positioned between the USB plug and the shield member on opposing sides of the USB plug to allow the USB plug to float for alignment.

Another general aspect relates to wherein the foam is conductive on the side of the USB plug that has a standard metal shield and the foam is non-conductive on the opposing side of the USB plug.

Another general aspect relates to wherein the housing body further comprises surface features proximate the transparent screen, the surface features being configured on the housing body to correspond to a position of software buttons on the touchscreen of the device.

Another general aspect relates to wherein the housing body further comprises controls, the controls being positioned on an exterior of the housing body and configured to actuate buttons on the electronic device within the cavity, the controls being configured to provide a hermetical seal between the exterior surface of the housing body and the cavity.

The foregoing and other features, advantages, and construction of the present disclosure will be more readily apparent and fully appreciated from the following more detailed description of the particular embodiments, taken in conjunction with the accompanying drawings.

### BRIEF DESCRIPTION OF THE DRAWINGS

Some of the embodiments will be described in detail, with reference to the following figures, wherein like designations denote like members.

FIG. 1 is a front perspective view of an embodiment of a protective communication system and cover for an electronic device in accordance with the present disclosure.

FIG. 2 is a front perspective view of an embodiment of a protective communication system and cover for an electronic device in another position in accordance with the present disclosure.

FIG. 3 is a front perspective view of components of an embodiment of a protective communication system for an electronic device in accordance with the present disclosure.

FIG. 4A is a front view of an electronic device housing/cover in accordance with the present disclosure.

FIG. 4B is a side view of the electronic device housing/cover depicted in FIG. 4A in accordance with the present disclosure.

FIG. 5A is a back view of an electronic device housing/cover in accordance with the present disclosure.

FIG. 5B is a side view of the electronic device housing/cover depicted in FIG. 5A in accordance with the present disclosure.

FIG. 6A is a top perspective view of the electronic device housing/cover in accordance with the present disclosure.

FIG. 6B is a top perspective view of the electronic device housing/cover in accordance with the present disclosure.

FIG. 7A is a front view of the electronic device housing/cover in accordance with the present disclosure.

FIG. 7B is a cross-sectional view of the electronic device housing/cover taken along line C-C of FIG. 7A in accordance with the present disclosure.

FIG. 8 is a partial cross-sectional view of the cut-away A from FIG. 7B in accordance with the present disclosure.

FIG. 9 is a partial cross-sectional view taken along the line D-D from FIG. 6B in accordance with the present disclosure.

### DETAILED DESCRIPTION OF EMBODIMENTS

A detailed description of the hereinafter described embodiments of the disclosed apparatus and method are presented herein by way of exemplification and not limitation with reference to the Figures listed above. Although certain embodiments are shown and described in detail, it should be understood that various changes and modifications may be made without departing from the scope of the appended claims. The scope of the present disclosure will in no way be limited to the number of constituting components, the materials thereof, the shapes thereof, the relative arrangement thereof, etc., and are disclosed simply as an example of embodiments of the present disclosure.

As a preface to the detailed description, it should be noted that, as used in this specification and the appended claims, the singular forms “a”, “an” and “the” include plural referents, unless the context clearly dictates otherwise.

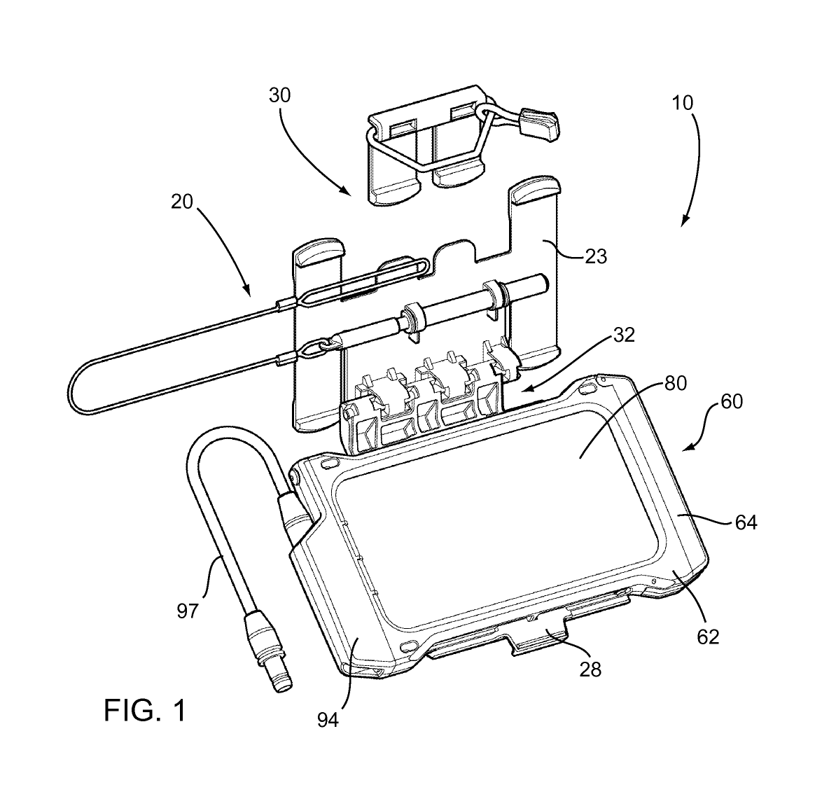

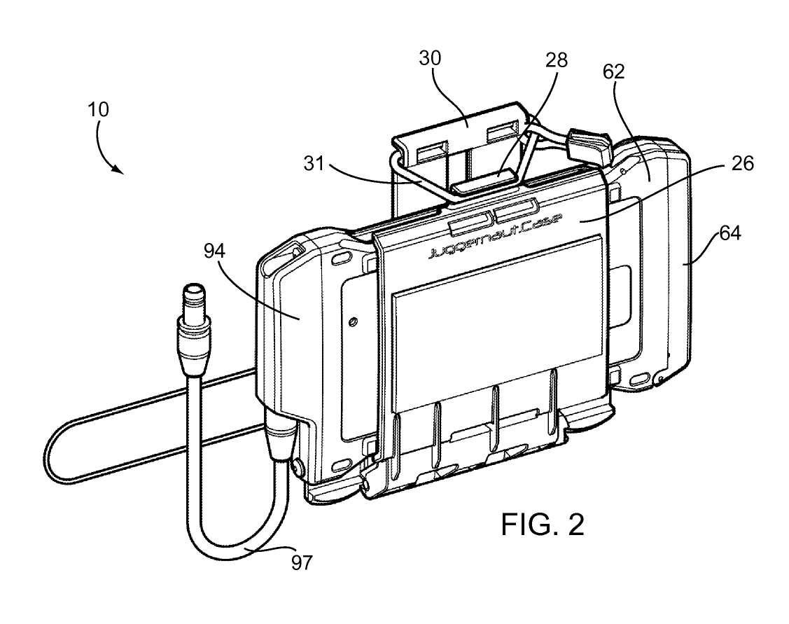

Referring to the drawings, FIGS. 1-3 depict an embodiment of a protective communication system 10 for an electronic device. Embodiments of the system 10 may comprise a coupling member 20, a retaining member 30, and an electronic device housing 60. The coupling member 20 and the device housing 60 may be physically configured to be functionally coupled to one another and thereafter move with respect to one another to arrange the system 10 in a closed position (a first position), depicted in FIG. 2, or an open position (second position), depicted in FIG. 1, or any position therebetween, if needed. The system 10 may further comprise the retaining member 30 that is configured to retain the coupling member 20 and the device housing 60 in a closed position with respect to one another. By releasing the retaining member 30 from the coupling member 20, the device housing 60 may permitted to move with respect to the coupling member 20 to transition the system 10 to an open position. In the open position, a user of the system 10 may operate an electronic touchscreen device 2 that is contained in the device housing 60. The touchscreen device 2 may be a computer, a tablet, and/or a cellular phone, or the like.

Embodiments of the system 10 may further comprise the retaining member 30 further comprising a latch member 31. The latch member 31 may be configured to rotate or otherwise pivot with respect to the retaining member 30. The latch member 31 may also be configured to functionally engage a hook member 28 of the coupling member 20 under the condition the system 10 is in the closed position, to be discussed in greater detail. As depicted, the latch member 31 may be a loop mechanism that is structurally configured to engage the hook member 28. However, embodiments of the system 10 include the latch member 31 being any fastening device now known or later developed that permits the latch member 31 to be functionally secured to the coupling plate 26 to retain the system 10 in the closed position. For example, latch member 31 may comprise a hook and loop fastener system, a button system, a snap system, a strap and buckle system, a magnetic release system or any other quick-release fastening mechanism. Further in example, the latch member 31 may be an elastic cord that stretches to secure around the hook member 28. Once secured around the hook member 28, the elasticity of the latch member 31 may secure, or otherwise retain, the system 10 in the closed position.

Embodiments of the system 10 may further comprise the coupling member 20 including a coupling plate 26. The coupling plate 26 may further comprise a hook member 28 that is configured to engage, catch, retain, hook, or otherwise secure the latch member 31 thereabout. By engaging the latch member 3 lto the hook member 28, the system 10 can be secured in the closed position. By disengaging the latch member 31 from the hook member 28, the system 10 is permitted to transition between the closed position and the open position.

Embodiments of the system 10 may further comprise the coupling member 20 including a coupling body 23. The coupling body 23 may include one or more prongs 22 having hooks 24 near the distal ends thereof, to be discussed in greater detail below.

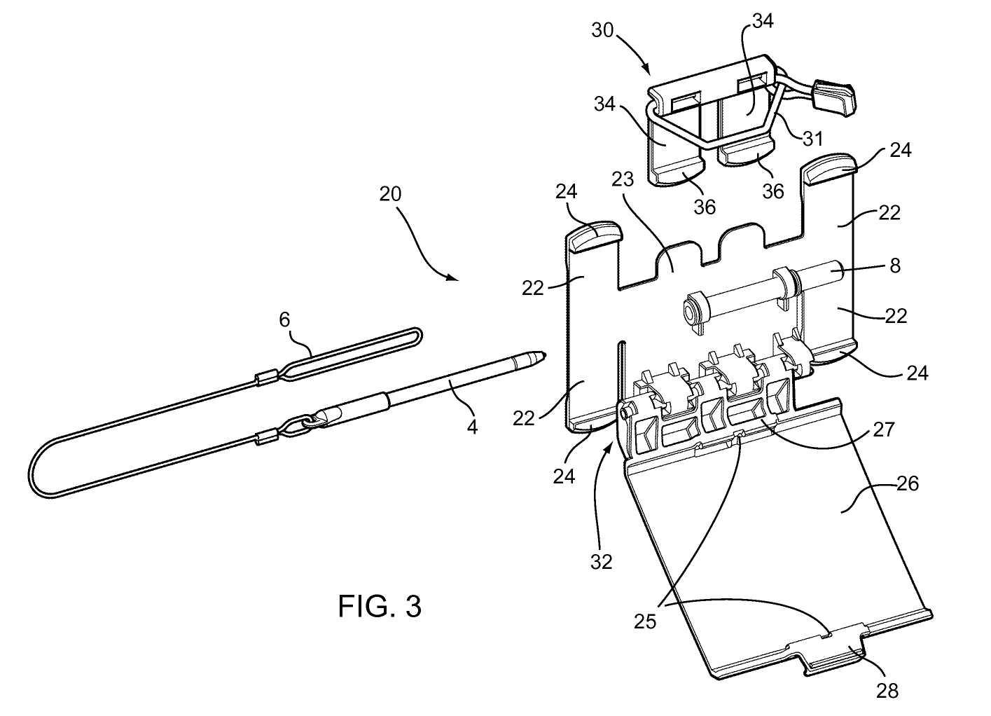

Embodiments of the system 10 may further comprise the coupling body 23 and the coupling plate 26 being configured to move with respect to one another. As depicted in FIG. 3, the coupling body 23 and the coupling plate 26 may be functionally coupled together about a joint 32. The joint 32 may be a continuous friction hinge that utilizes a spring pin or a roll pin or other friction providing member or mechanism. The joint 32 may be a constant torque hinge, a position hinge, a clutch hinge, a torque hinge, a detent hinge, or a piano hinge. The joint 32 should be configured to provide resistance against and prevent the device housing 60 from rotating about the joint 32 in an unintended manner. The user should have to apply force to the device housing 60 to cause the device housing 60 to pivot or rotate about the joint 32. The joint 32 may be any joint now known or hereinafter discovered that permits the coupling body 23 to move or pivot away from the coupling plate 26 to reveal the device housing 60, as will be described in detail below. The device housing 60 may be functionally coupled to the coupling plate 26, such that as the coupling plate 26 moves, so too does the device housing 60. The joint 32 may be protected by the combination of the device housing 60 and the coupling member 20.

Embodiments of the coupling member 20 may further comprise a stylus port 8 being releasably coupled to the coupling body 23 on a surface of the coupling body 23 that may reside proximate with the device housing 60, to thus protect the stylus port 8 between the coupling body 23 and the device housing 60, under the condition the system 10 is in the closed position. The stylus port 8 may be configured to receive and retain therein a stylus 4, the stylus 4 being configured to operate the device 2. The stylus 4 may be functionally coupled to the system 10 by way of a stylus retainer 6. To operate the stylus 4, a user may remove the stylus 4 from the stylus port 8 and use the stylus 4 to operate the device 2. When finished with the stylus 4, the user may insert the operational end of the stylus 4 into the stylus port 8, to thus store and protect the stylus 4.

In embodiments of the system 10, the device housing 60 may be releasably and repeatedly coupled to or decoupled from the coupling member 20, and in particular from the coupling plate 26 by way of notches 27. In this way, various sized device housings 60, which are sized, designed, and configured to match, or correspond to, the size, shape, and operational inputs/outputs of the various types and models of personal electronic touchscreen devices 2, can be coupled to the coupling member 20 and made part of the system 10 or detached therefrom and replaced by another size of device housing 60 that contains another sized electronic touchscreen device 2. Thus, the different-sized device housings 60 that are configured to correspond to the different types of electronic devices can be interchangeable with the coupling member 20. It follows that the coupling member 20 can be configured to be of one specific size, whereas the device housing 60 can be made in several shapes and sizes to accommodate the wide variety of personal electronic devices 2. In other words, any size device housing 60 can therefore be interchangeably coupled to the one-size-fits-all coupling member 20. To couple the device housing 60 to the coupling member 20, a user may place a notch 65 in a sidewall of the housing body 62 within a corresponding groove 25 in the coupling plate 26. The notch 65 and the groove 25 serve to position the device housing 60 in proper alignment with the coupling plate 26 to permit the device housing 60 to couple to the coupling plate 26.

At least one benefit of the coupling member 20, including the coupling body 23, being of one size is that the coupling member 20 may be configured to correspond to and couple into the Modular Lightweight Load-carrying Equipment (MOLLE) system, which is the standard equipment system currently employed by various militaries and other tactical operations units. MOLLE systems are based off of the Pouch Attachment Ladder System (PALS). The PALS webbing features 1″ wide straps that run horizontally and are spaced 1″ apart, with 1.5″ gaps between attachment points.

As mentioned above, embodiments of the system 10 may further comprise the coupling member 20 including a coupling body 23 that may include one or more prongs 22 having hooks 24 near the distal ends thereof. The prongs 22 of the coupling body 23 may be configured to engage the PALS webbing. Specifically, the prongs 22 may be inserted into the webbing and secured thereby. The prongs 22 may be configured to flex, or otherwise bend, to permit the prongs 22 to fit within the webbing. Yet, the prongs 22 are configured to be sufficiently rigid to securely retain the coupling body 23 to the MOLLE system once functionally attached thereto. The prongs 22 may be configured to correspond to the dimensions of the PALS webbing, such that the prongs 22 make a secure and snug fit with the PALS webbing. In other words, the prongs 22 may be spaced apart a predetermined distance from one another to correspond to the distance between gaps in the PALS webbing. Likewise, the length of the prongs 22 may be a predetermined length to permit each of the prongs 22 to pass completely under one of the straps in the PALS webbing. To this end, on the distal end of each prong 22, a hook 24 may be configured to engage the straps under which the respective prong 22 has been placed/coupled. In this way, the hook 24 serves to prevent the prong 22 from sliding out of, or otherwise disengaging from, the webbing, without the application of undue force.

Embodiments of the system 10 may further comprise the retaining member 30 having one or more prongs 34 thereon that also have hooks 36 near the distal ends thereof. Similarly to the prongs 22 and hooks 24 described above with respect to the coupling member 20, the prongs 34 and hooks 36 of the retaining member 30 may also be configured to engage the PALS webbing. Specifically, the prongs 34 may be inserted into the webbing and secured thereby. The prongs 34 may be configured to flex, or otherwise bend, to permit the prongs 34 to fit within the webbing. Yet, the prongs 34 are configured to be sufficiently rigid to securely retain the retaining member 30 to the MOLLE system once functionally attached thereto. The prongs 34 may be configured to correspond to the dimensions of the PALS webbing, such that the prongs 34 make a secure and snug fit with the PALS webbing. In other words, the prongs 34 may be spaced apart a predetermined distance from one another to correspond to the distance between gaps in the PALS webbing. Likewise, the length of the prongs 34 may be a predetermined length to permit each of the prongs 34 to pass completely under one of the straps in the PALS webbing. To this end, on the distal end of each prong 34, a hook 36 may be configured to engage the straps under which the respective prong 34 has been placed/coupled. In this way, the hook 36 serves to prevent the prong 34 from sliding out of, or otherwise disengaging from, the webbing, without the application of undue force.

Embodiments of the system 10 may further comprise the retaining member 30 being positioned on MOLLE system of the user with respect to the coupling member 20 such that the retaining member 30 and the coupling member 20 may allow the latch member 31 to functionally engage the hook member 28 to secure the system 10 in the closed position and to efficiently release the latch member 31 from the hook member 28, when desired, to allow the system 10 to transition to the open position.

In view of the above, under the condition that each of the prongs 22 and 34 has been properly coupled to the MOLLE system, as described above, the system 10 thereafter moves with the movement of the vest, and thus the movement of the user. In other words, as the user moves, so too does the vest, and so too does the system 10. It follows then, that the user of the vest may wear the vest and attach thereto the system 10, which then travels with the user without the user having to carry the system 10 by hand. This frees the user's hands to accomplish other important tasks, while all the while the user's device 2 is kept in operational reach of the user for quick tactical communication when needed.

Furthermore, embodiments of the system 10 include the advantage that once the coupling member 20 has been properly secured to the vest, the user may desire to remove the device housing 60 from the coupling member 20 and replace the removed device housing 60 with another device housing 60 that contains a different-sized electronic touchscreen device 2. Thus, variously sized device housings 60 containing respective electronic touchscreen devices may be interchangeable with the coupling member 20, as described in greater detail above.

In embodiments of the system 10, once the system 10 is operationally attached to the vest, the system 10 may rest in the closed position, which positions the system 10 up against the vest and out of the way of the user. But, if the user desires or needs to use the electronic touchscreen device 2 contained in the system 10, the user may disengage the latch member 31 from the hook member 28 to permit the coupling plate 26, and thus the device housing 60, to pivot away from the coupling body 23, which is coupled to the user's vest, as described above, to reveal the device housing 60, which holds the electronic touchscreen device 2 therein.

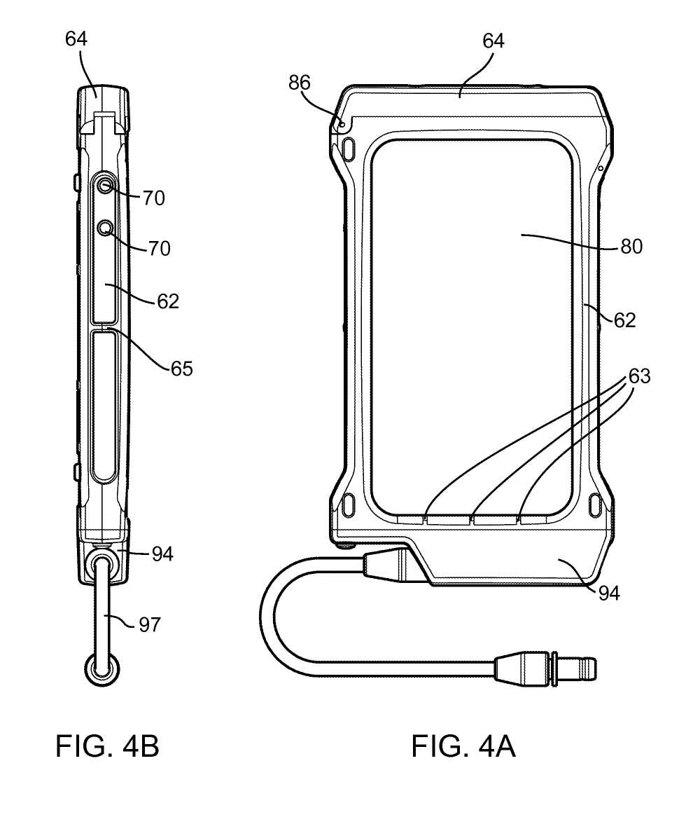

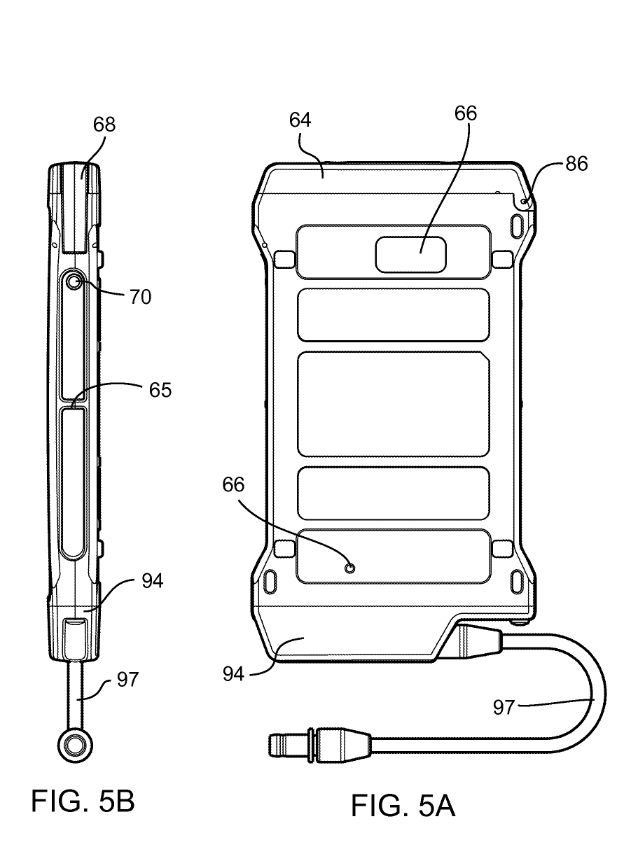

As depicted in FIGS. 4A-6B, embodiments of the system 10 may include the device housing 60 further comprising a housing body 62, a housing lid 64, communication ports 66, and a securing latch 68. The housing body 62 may be a unitary design that has no seams, except at a single opening, and the housing body 62 configured to define a cavity 63 therein. The unitary form of the housing body 62 is configured such that the housing body 62 is thus water sealed. The housing body 62 may have an opening in a top portion thereof, the opening being the only entrance into the cavity 63. The housing lid 64 may be configured to engage the housing body 62 to access the opening whereby the user may access the cavity 63, wherein a personal electronic device 2 (end-user device 2) may be secured. The housing lid 64 may further serve to seal the opening to the cavity 63.

Embodiments of the device housing 60 may further comprise the communication ports 66 being configured in the housing body 62, the housing lid 64, or both, to correspond to the input/output components of the personal electronic device/end-user device 2. In this way, the speaker, microphone, audio/visual inputs, USB port, camera, camera flash, and/or power inputs, just to name a few of the various ports and input/output components on many electronic devices, can function with their intended purpose without the system 10 impeding the performance. For example, a user can speak through one of the communication ports 66 and into the microphone on the electronic device 2 and the user can listen through another one of the communication ports 66 that corresponds to the speaker on the electronic device 2. Additional communication ports 66 correspond to other input/output components of the electronic device 2, such that the performance of the electronic device 2 is not diminished by the device 2 being placed within the system 10. For example, the communication ports may be see-through ports that permit the device 2 to perform desired functions, yet remain hermetically sealed within the device housing 60, such as the communication ports 66 in the back of the housing body 62 that is clear and provides that the user of the device 2 may take a picture. The device housing 60 may have a plurality of communication ports 66. Alternatively, the device housing 60 may not have any communication ports 66. Additionally, the device housing 60 may only have those communication ports 66 that permit the device housing 60 to remain hermetically sealed with the device 2 inside.

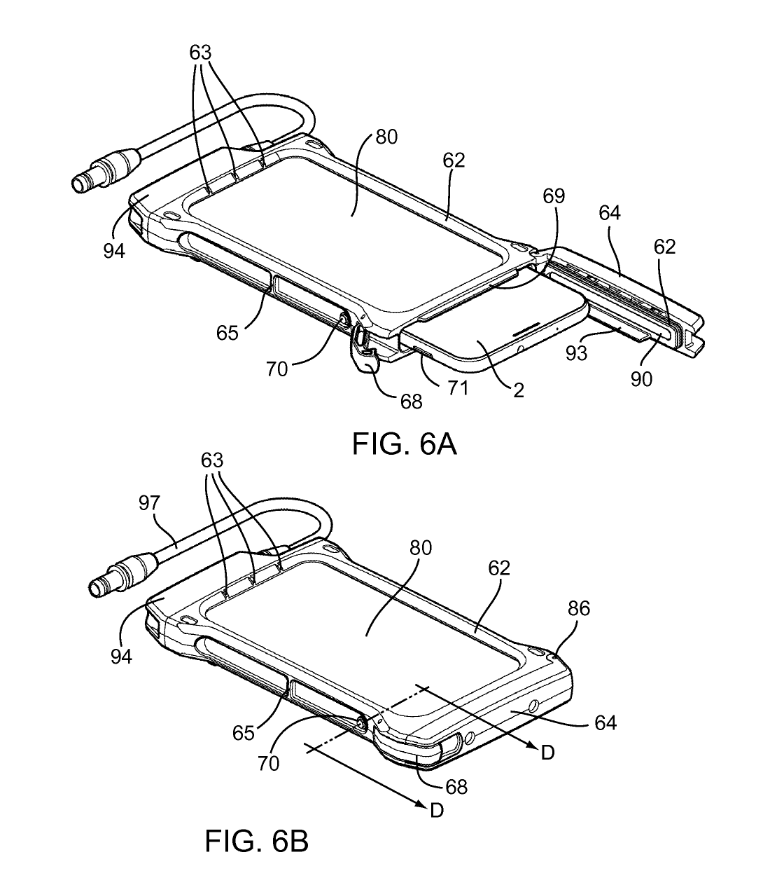

The securing latch 68 may configured to latch, secure, or otherwise retain, the housing lid 64 to the housing body 62 under the condition that the securing latch 68 is in the latched position, as depicted in FIG. 6B. The securing latch 68 is further configured to release the housing lid 64 from the housing body 62, such that the housing lid 64 may rotate, pivot, or otherwise move with respect to the housing body 62, under the condition that the securing latch 68 is in the unlatched position, as depicted in FIG. 6A. With the housing lid 64 in a top portion of the housing body 62, the device 2 must be inserted into the cavity 63 through the opening between the housing body 62 and the housing lid 64. By this configuration, the device 2 may more easily connect to the communication and data transfer assembly 94 positioned on an opposing surface within the cavity 63 to the housing lid 64. This reduces the possibility that the insertion of the device 2 within the cavity 63 will place undue and damaging torque on the communication and data transfer assembly 94 or the USB interface port on the device 2 itself

Embodiments of the device 10 include the housing body 62 further comprising surface features 63 near the protective screen 80 proximate the base of the housing body 62, or near the USB interface assembly 94. The surface features 63 may comprise ridges, raised portions, or other tactile features that are spaced apart a given distance. The surface features 63 are oriented and configured such that the surface features 63 correspond to a position of a soft operational control of the user's device 2. End-user devices 2 may have soft operational controls, such as a menu button, a home-screen button, a back-one-page button, a search button, and the like, that are utilized by the user to operate, or otherwise navigate through, the device 2. The surface features 63 are configured to correspond to these soft operational controls on the device 2, the soft operational controls being software driven controls that show up on the touchscreen of the device 2. It follows that because of the position of the surface features 63, a user may use the surface features 63 to locate by touch alone the various soft operational controls built into the software of the user's device 2 and displayed at the base of the screen/display of the user's device 2. In other words, by touch or tactile sensation, a user may locate the position of each of the soft operational controls on the user's device without visually having to locate these same soft operational controls. This provides the benefit that a user of the system 10 need not visually look away from an intended target or object to locate and thereafter operate the soft operational controls of the device 2.

Embodiments of the system 10 include the device housing 60 further comprising a screen protector 80. Embodiments of the screen protector 80 may be configured in the housing lid 64 and function to protect the device 2. The screen protector 80 may be fixedly coupled to the housing body 62 by adhesive 81, such as glue, epoxy, or the like. The screen protector 80 may be shatter proof. The screen protector 80 may be comprised of Plexiglas® or acrylic glass compositions. The screen protector 80 may be comprised of other clear plastic composites that are resistant to breaking The screen protector 80 may be comprised of chemically strengthened glass compositions, similar to Gorilla® Glass made by Corning®. The screen protector 80 may be scratch-resistant and impact-resistant. The screen protector 80 may also have capacitive characteristics.

The screen protector 80 may be configured to correspond to the size of the touchscreen of the device 2 over which the screen protector 80 will be placed. Moreover, once the screen protector 80 is positioned over the end-user device 2, the screen protector 80 is configured to allow the user to activate, manipulate, or otherwise operate, the touchscreen display of the end-user device 2 through the screen protector 80. In other words, the screen protector 80 does not impede the device 2, and in particular the touchscreen of the device 2, from sensing the bioelectricity in the user's skin or bioelectric glove that operates the device 2. In this way, while the end-user device 2 is secured within the system 10, and in particular behind the screen protector 80, the user may operate the touchscreen of the device 2 through the screen protector 80 without having to remove the device 2 from the system 10 to do so.

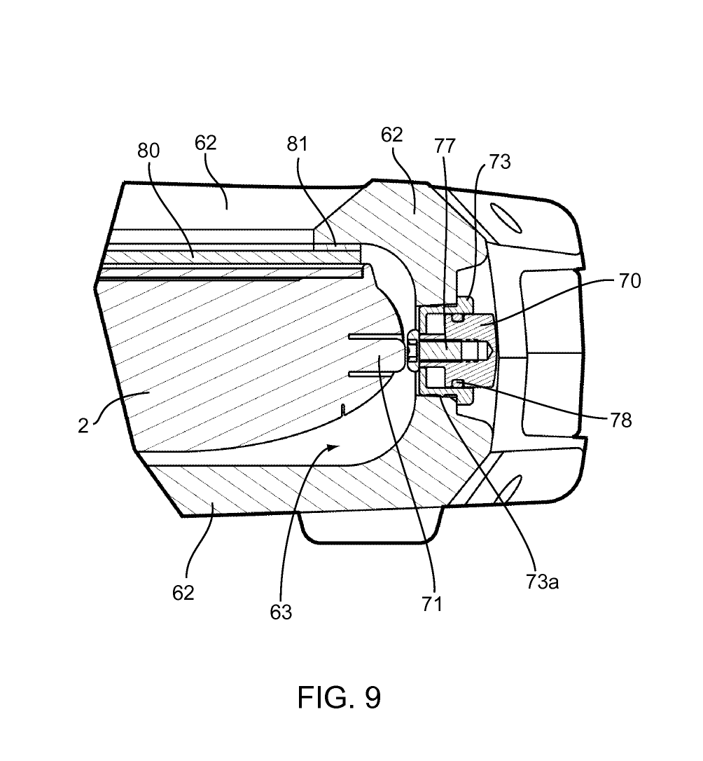

Referring now to FIG. 9, embodiments of the system 10 may include the device housing 60 further comprising controls 70. The controls 70 of the system 10 may be positioned on the housing body 62 and may be configured to correspond to the operational buttons 71 of the end-user device 2. The controls 70 may be positioned in a sidewall of the housing body 62. For example, many end-user devices 2 have hard operational buttons 71, such as a power button, a volume button, a mute button, or the like, that are utilized to operate, or otherwise navigate, the device 2. The controls 70 are configured to correspond to these hard operational buttons 71 on the device 2, the hard operational buttons 71 being physically located on the exterior surfaces of the device 2. Operation of the controls 70 allows the user to operate these hard operational buttons 71 on the device 2 without having to remove the device 2 from the system 10 to do so.

The controls 70 may positioned in an easy to reach portion of the housing body 62, such that they are readily accessible to the user. Embodiments of the system 10 may comprise the control 70 further comprising a control housing 73, housing barbs 73a on an exterior surface of the control housing 73, and a plunger 77. Portions of the control 70 may be confined within the control housing 73 and be configured to move with respect to the control housing 73 in a press-fit configuration. The control 70 may be further configured with a plunger 77. The control 70 may be further configured with a sealing member 78, such as an O-ring, that may be operatively positioned in the sidewall of the control 70 and configured to make contact with the interior of the control housing 73. The control housing 73 may be functionally coupled to the housing body 62, such that the control housing 73 does not move with respect to the housing body 62. Further, the housing barbs 73a may be positioned between the control housing 73 and the housing body 62 to prevent the control housing 70 from displacing with respect to the housing body 62 upon application of a user-applied force. The housing barbs 73a may also prevent the ingress of environmental contaminants into the cavity 63 between the interface of the housing body 62 and the control housing 73. When a user applies force to the control 70, the control 70 transitions with respect to the control housing 73, thus causing the plunger 77 to move within the cavity 63 and depress against the hard operational button 71 on the device to thereby depress and actuate the button 71 and activate the function associated with the button 71. In this way, the user may operate the hard operational buttons 71 of the device 2 without having to remove the device from the device housing 60. Moreover, the sealing member 78 prevents the ingress of environmental contaminants from entering the cavity 63 through the interface of the control 70 and the control housing 73.

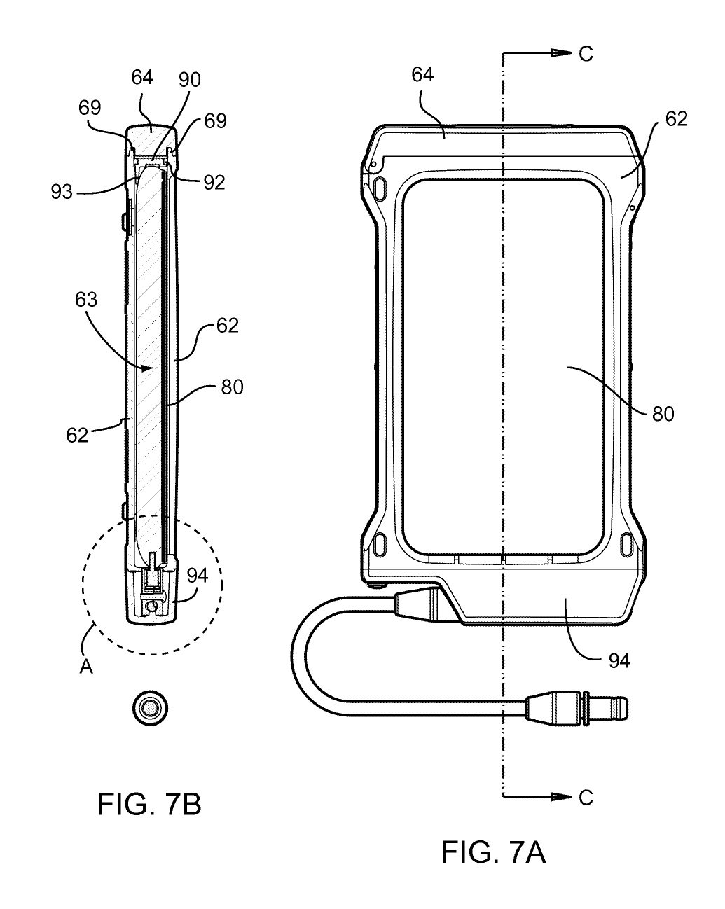

Referring now to FIGS. 6A, 6B and 7B, and as mentioned above, the housing lid 64 may be configured to move with respect to the housing body 62. The housing lid 64 may be configured to pivot or rotate with respect to the housing body 62 about a pivot point 86. The pivot point 86 may be a joint or other connection means that permits the housing lid 64 to rotate off and away from the housing body 62. Under the condition that the housing lid 64 has been rotated away from the housing body 62, the cavity 63 is revealed and the user may insert therein the device 2. Thereafter, the housing lid 64 may be rotated back toward the housing body 62 to engage the housing body 62. Once engaged, the device 2 is secured within the device housing 60 and ready to be used by the user.

Referring still to FIGS. 6A, 6B and 7B, to provide that the housing lid 64 engages the housing body 62 and hermetically seals the opening to the cavity 63, the housing lid 64 may further comprise an internal plateau 90 on the interior face of the housing lid 64. The housing lid 64 may further comprise a sealing member 92, such as an O-ring, positioned at or near the base of the plateau 90. The plateau 90 and sealing member 92 may be configured to correspond to and cooperate with a protrusion 69 on a lip surface of the housing body 62 near the opening of the cavity 63. The protrusion 69 may be configured on either side of the lip surface near the opening of the cavity 63 and may further be configured to engage the housing lid 64 between the plateau 90 and an exterior surface of the housing lid 64. In this way, the protrusion 69 may be secured against and functionally engage the sealing member 92 that surrounds the plateau 90. Additionally, the plateau 90 and sealing member 92 may be configured to correspond to and cooperate with and an interior surface of the cavity 63. Under the condition that the housing lid 64 is brought into proximity with the housing body 62 and functionally engages the same, the sealing member 92 may engage each of the protrusions 69 and the cavity 63 to seal the housing lid 64 to the housing body 62 to prevent the ingress of contaminants into the cavity 63 between the housing lid 64 and the housing body 62, as depicted in FIG. 7B. The housing lid 64 may further comprise a positioning member 93 that protrudes into the cavity 63 under the condition the housing lid 64 is coupled to the housing body 62. The positioning member 93 may be configured to slide under the back side of the device 2 to properly position the device 2 within the cavity 93 and prevent the device 2 from experiencing unwanted movement therein.

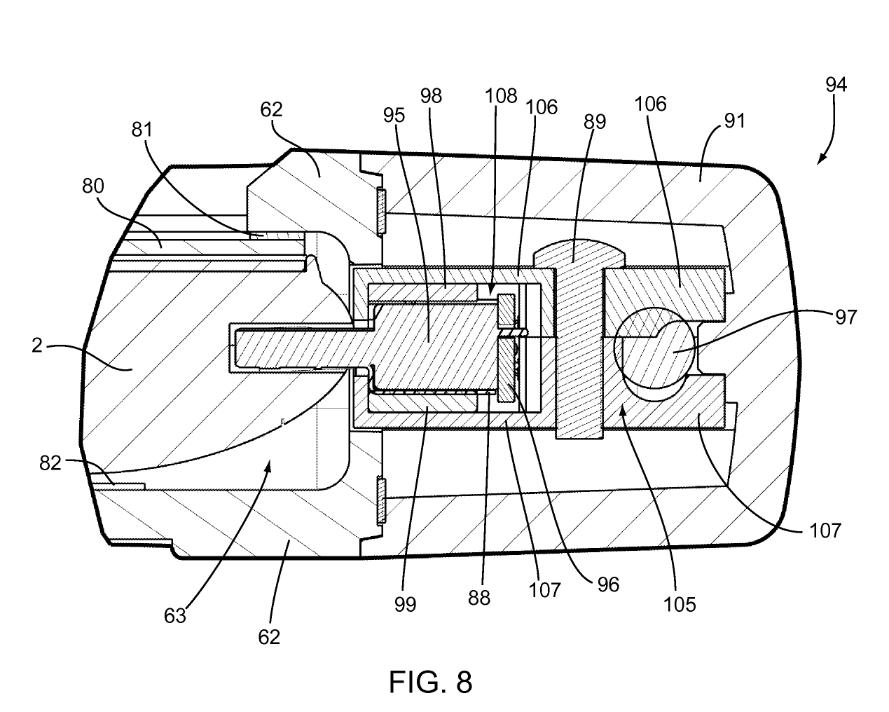

Embodiments of the system 10 include the housing body 62 further comprising resilient members 82, depicted in FIG. 8, positioned within the housing body 62, i.e., in the cavity 63, and on interior surfaces thereof. Resilient members 82 may be positioned on the bottom interior surface of the housing body 62, so as to contact the rear plate of the end-user device 2, and on the side interior surfaces of the housing body 62, so as to contact the side surfaces of the end-user device 2. The resilient members 82 may function to provide cushion and resilient support to the device 2 within the cavity 63. The resilient members 82 may prevent damage to the device 2, when the device 2 is positioned within the cavity 63. The resilient members 82 may function to press the device 2 upward against the screen protector 80 to allow the user to operate the device 2 through the screen protector 80, as described above. The resilient members 82 also provide some give during use/transportation of the device 2, such that sudden impacts to the system 10 or sudden movements by the user can be absorbed by the resilient members 82 instead of being absorbed by the components of the device 2, which may damage the device 2.

With reference to the Figures, and in particular FIG. 9, embodiments of the system 10 include the housing body 62 further comprising one or more communication and data transfer ports 94, such as a USB interface port, that may functionally couple to the housing body 62 and operationally couple to the device 2 to allow the device 2 to communicate with and transfer data to and from external devices. The communication and data transfer assembly 94 may be configured to allow wires and/or cables 97 to be connected to the device 2 through the communication and data transfer assembly 94, such that the device 2 may be electronically coupled to other external components, such as, for example, power sources, batteries, modems, antennas, computers, routers, or other electronic devices. By way of example, an external power source, such as a battery, may be carried by the user on his/her person in a backpack or pocket. The external battery source may be connected to the device 2 in the system 10 by running a cable 97 from the battery carried by the user to the communication and data transfer assembly 94, which may be connected to the device 2 via the USB port on the device 2. In other words, via the communication and data transfer assembly 94 the device 2 can be connected to other devices or components, while the device 2 is nevertheless being concealed/protected in the system 10.

With reference still to FIG. 9, embodiments of the system 10 may further comprise the communication and data transfer assembly 94 being configured to shield the communication and data transfer between the device 2 and the assembly 94 and/or between the device 2 and an external electronic device from an environment that typically contains high levels of electromagnetic interference (EMI) that might otherwise interfere with communication to and from the device 2. The assembly 94 may comprise a port housing 91, a shield member 105 having a top end 106 and a bottom end 107, a USB plug 95, a fastening member 89, a non-conductive foam 98, and a conductive foam 99. The assembly 94 may be configured to encase at least the USB plug 95 in a conductive metal material, such as, but not limited to, aluminum, copper, nickel, lead, or the like, that serves to block the EMI that might otherwise interfere with the data transfer taking place between the device 2 and the assembly 94 and/or between the device 2 and an external electronic device.

The assembly 94 may thus comprise a shield member 105 positioned within the port housing 91. The shield member 105 may comprise a top end 106 and a bottom end 107 that are configured to be fastened together by fastening member 89. The fastening member 89 holds the top end 106 and bottom end 107 together such that the seams between the top end 106 and bottom end 107 are held together tightly to reduce the possibility that voltage may be created at the seam. For the seams to be tight, the top and bottom ends 106 and 107 should correspond to one another and oppose one another. The top and bottom ends 106 and 107 may also be configured to create a nook 108 therebetween. The USB plug 95 may be configured within the nook 108 to thus protect the USB plug 95 from EMI and seal the plug from EMI emissions. Additionally, the top and bottom ends 106 and 107 may be configured to provide an opening in a side portion thereof, wherein portions of the USB plug 95 may extend through the shield member 105. The shield member 105 may be further configured within the port housing 91 such that the portion of the USB plug 95 that extends out of the shield member 105 may enter into the cavity 63 through an opening in the housing body 62 at the interface of the housing body 62 and the assembly 94. The portion of the USB plug 95 that enters the cavity 63 may be configured to make physical and electrical contact with the device 2 within the cavity 63. Further, the interface between the housing body 62 and the assembly 94 may be hermetically sealed to prevent the ingress of environmental contaminants into the cavity 63 and within the assembly 94.

Embodiments of the assembly 94 may further comprise a non-conductive foam and a conductive foam 99 being positioned between the USB plug 95 and the shield member 105 on opposing sides of the USB plug 95. A conventional USB plug 95 may be configured with a metal shield on one side portion of the USB plug 95 for shielding the USB plug 95 from EMI, whereas the opposing side portion of the USB plug 95 may not have the same metal shield thereon. Accordingly, the assembly 94 may further comprise the conductive foam 99 being positioned between the USB plug 95 and the shield member 105 on the side of the USB plug 95 that has the conventional metal shield 88, and the non-conductive foam 98 being positioned between the USB plug 95 and the shield member 105 on the opposing side of the USB plug 95 that does not have the conventional metal shield 88 thereon. The conductive foam 99 may be configured to make physical and electrical contact with the conventional metal shield 88 on the USB plug 95 and with the shield member 105. In this way, the shield member 105 serves to block the majority of external EMI that attempts to interfere with the performance of the USB plug 95, and the conductive foam 99 provides further protection against external EMI that might be able sneak past the shield member 105 and enter the nook 108. The conductive foam 99 may be a sink for the EMI that might be able to enter the nook 108. In other words, the conductive foam 99 provides a place for the energy to go besides the USB plug 95. As such, the external EMI is prevented from interfering with the performance of the USB plug 95. In addition, the shield member 105 may be configured to contain therein the EMI that might be produced by the components within the nook 108. In other words, the shield member 105 may serve to block the EMI that is emitted by the USB plug and its component parts. The shield member 105 may be further configured to house the printed circuit board (PCB) of the USB plug 95 and the initial wiring stemming from the PCB. The shield member 105 may be further configured with a metal casing or wrap that encases the wiring 97 as it leaves the shield member 105. Such a configuration helps prevent the EMI from entering the shield member 105.

Embodiments of the assembly 94 may further comprise the foams 98 and 99 being configured to serve as shock absorbers or padding for the USB plug 95. At times, the system 10 and/or the device 2 may be dropped, jolted, jarred, or otherwise bumped, which may cause torque or stress on the interface between the device 2 and the USB plug 95. Accordingly, the USB plug 95 may be configured to “float” or otherwise move with respect to the device 2 within the shield member 105. Thus, the foams 98 and 99 may be configured to not only absorb some of the shock that may be inflicted on the system 10 and/or the device 2, but the foams 98 and 99 may allow the USB plug 95 to remain within the shield member 105 and yet move with the device 2 so as to not permit excessive torque or stress to damage the interface between the USB plug 95 and the device 2. Further, the USB plug 95 may be configured to “float” such that upon initial connection with the device 2, there is some give or leeway for the device 2 to make initial physical alignment and electrical contact with the USB plug 95. After which, the foams 98 and 99 permit the USB plug 95 to move with the device 2 and yet remain within the shield member 105.

Once the device 2 is positioned within the system 10, the device 2 is relatively protected from impact damage. The system 10 is comprised of rigid polymer materials that resist impact. In the closed position, the user's own body protects the front of the device 2 from receiving damaging impact, whereas the front plate 26 of the coupling member 20 protects the device 2 from impact from the underside of the device 2. In the open position, the front plate 26 of the coupling member 20 continues to protect the device 2 from impact from the underside of the device 2, whereas the user's hand may protect the front of the device 2 while the user operates the device. Moreover, in tactical situations, by having the device 2 coupled to the user's chest, the user does not have to use two hands to access and operate the device 2. For example, the configuration of the system 10, as described above, is such that the user may use one hand to release the system 10 from the closed position and transition the system 10 to the open position to access the device 2 within the device housing 60. The user's vest holds the system 10 in place during operation of the device 2. Then, the user need only use one hand to operate the features of the device 2 within the device housing 60. The conductive nature of the screen protector 80 and the controls 70 allow the user to interact with and use the device 2 in the system 10. Again, the configuration of the system 10 allows the user to use one hand to access, operate, and then store the device 2 during tactical operations. This provides the advantage that the user may leave one hand on a weapon that the user is using while using the other hand to communicate through the device 2. When finished with the device 2, the device 2 can then be quickly and safely stored by moving the device housing 60 to the closed position and securing the latch member 31, as described above.

Under the condition that the system 10 is in the open position, which places the operational aspects of the device 2 within reach of the user, the joint 32 may be configured to come to a stop to prevent the device housing 60 from pivoting further away from the coupling body 23. This provides the functional advantage that the user may push down on the screen protector 80 and/or the controls 70 to operate the device 2 without the device 2 further pivoting away from the user. In other words, because the joint 32 may be configured to come to a stop, the device housing 60 is prohibited from further rotation and remains substantially orthogonal to the coupling body 23, as depicted in FIG. 1. This provides the best angle for the user to operate the device.

Embodiments of the system 10 may further include the concept that the device housing 60 may be hermetically sealed from outside contamination. As such, each of the moving parts of the system 10 that communicate with the device housing 60, such moving parts comprising, for example, the housing lid 64, the screen protector 80, the communication port 94, the buttons 70, comprise the component parts of the system 10, may be configured to interface with the device housing 60 so that the interface is sealed from outside or environmental contaminants or the ingress of such contaminants. One way this is accomplished is requiring that only two moving parts can couple to one another to hermetically seal the cavity 63 at any point on the device housing 60. This requirement limits the number of components that must interact with one another to provide the hermetic seal. As such, the component parts of the system 10 that interact with the device housing 60 are limited to interact only with the device housing 60.

Embodiments of the system 10 include an appendage mount 100 (not depicted) that is configured to be repeatedly and releasably coupled to an appendage of a user and also configured to be repeatedly and releasably coupled to the device housing 60, such that the appendage mount 100 secures the device housing 60 functionally and securely to the appendage of the user. The appendage mount 100 may further include an appendage mount engagement portion 110 and an appendage strap 130.

Embodiments of the appendage mount engagement portion 110 include a top surface 112 that is configured to functionally engage and secure thereto the device housing 60, in much the same way the coupling member 20 is configured to functionally engage and secure thereto the device housing 60. In this way, the device housing 60 is configured to not only engage the coupling member 20, described above, but also to alternatively engage the appendage mount 100, if needed or desired by the user. Indeed, embodiments of the system 10 include the appendage mount 100 and the device housing 60 being configured to releasably and repeatedly couple to or decouple from one another. In particular, the appendage mount engagement portion 110 and its top surface 112 are configured to functionally engage the device housing 60 on the bottom of the housing lid 64 to thereby secure the device housing 60 to the appendage mount 100. In this way, various sized device housings 60, which are sized, designed, and configured to match, or correspond to, the size, shape, and operational inputs/outputs of the various types and models of personal electronic touchscreen devices 2, can be coupled to the top surface 112 and made part of the system 10 or detached therefrom and replaced by another size of device housing 60 that contains another sized electronic touchscreen device 2. Thus, the different-sized device housings 60 that are configured to correspond to the different types of electronic devices can be interchangeable with the top surface 112. It follows that the top surface 112 can be configured to be of one specific size, whereas the device housing 60 can be made in several shapes and sizes to accommodate the wide variety of personal electronic devices 2. In other words, any size device housing 60 can therefore be interchangeably coupled to the one-size-fits-all top surface 112.

Embodiments of the appendage mount engagement portion 110 include an appendage strap 130 that is configured to wrap around an appendage of a user, or other object, if desired. The appendage strap 130 is comprised of flexible, yet durable, material that is capable of being cinched against the appendage of the user to tighten the appendage mount 100 to the user, or other object. The appendage strap 130 may be configured to releasably couple to the appendage mount engagement portion 110, whether on a bottom surface, a side surface, or a top surface thereof. Alternatively, the appendage strap 130 may be configured to be fixedly coupled to the appendage mount engagement portion 110, such that the appendage strap 130 and the appendage mount engagement portion 110 are fixed to one another. Nevertheless, despite being releasably coupled or fixed, the interface between the appendage strap 130 and the appendage mount engagement portion 110 allows the appendage strap 130 to flex, bend, rotate, pivot, or otherwise move, with respect to the appendage mount engagement portion 110. In this way, the appendage mount 100 is flexible enough to fit over large and small appendages or objects.

Embodiments of the appendage strap 130 may include the appendage strap 130 having a flexible member 132 that engages the appendage mount engagement portion 110 and the appendage strap 130, such that the flexible member 132 provides the structural and functional communication between the appendage mount engagement portion 110 and the appendage strap 130. The flexible member 132 may be a hook and loop fastener system, a buckle system, a snap fastener system, a zipper fastener system, any other known fastener system, or an elastic material stitched, or otherwise coupled to the appendage strap 130, as depicted.

Embodiments of the appendage strap 130 may include the appendage strap 130 comprising a flexible material or a material that is capable of being bunched together to decrease its circumference around an object. As depicted, the appendage strap 130 may be comprised of semi-rigid portions 134 that maintain a certain desired shape, but yet are malleable and flexible. In between these semi-rigid portions 134, the appendage strap 130 may comprise weaker portions 136 that aren't configured to maintain a certain desired shape, but are configured to functionally connect the semi-rigid portions 134 together and configured to be bent, shaped, bunched, or moved, as needed to decrease the circumference of the appendage strap 130.

Embodiments of the appendage strap 130 may include the appendage strap 130 further comprising a fastening means 140. The fastening means 140 is configured to tighten the appendage strap 130 around an appendage of a user or around an object. The fastening means 140 is further configured to tighten the appendage strap 130 around objects having variously-shaped cross-sections, such as circles, squares, triangles, just to name a few. The appendage strap 130 is flexible enough to fit around any cross-sectional shape of an object. Moreover, the fastening means 140 is configured to tighten the appendage strap 130 firmly and securely around such cross-sectional shapes, such that the appendage strap 130, and thus the appendage mount 100, and thus the system 10, does not move with respect to the object or appendage about which the system 10 is attached. As the fastening means 140 is tightened, the circumference of the appendage strap 130 correspondingly decreases to securely fit the appendage mount 100 to the appendage or object. Likewise, as the fastening means 140 is loosened, the circumference of the appendage strap 130 increases and the appendage mount 100 may be removed from the appendage or object, either by sliding the appendage mount 100 of one distal end of the appendage or object or by releasing one of the flexible members 132 from the appendage mount engagement portion 110 to permit the appendage mount 100 to be decoupled from the appendage or object about which it was secured.

As depicted, the fastening means 140 may be a reel and a lace cable system capable of quickly and efficiently tightening the appendage mount 100 to an appendage or object. The reel and lace cable system can be a closure system similar to those manufactured by Boa®. The closure system may comprise a reel 142, a cable 144, and loop fasteners 146. The cable 144 may be secured on each of its distal ends to the appendage strap 130 and the cable may travel back and forth across the appendage strap 130 around the loop fasteners 146 on one side of the appendage strap 130 and into the reel 142 on an opposing side of the appendage strap 130. By adjusting the reel 142, the cable 144 is thereby tightened or loosened accordingly, which results in the cable 144 tightening or loosening, as the case may be, about the appendage strap 130 to reduce the circumference of the appendage strap 130 to thereby tighten or loosen the appendage strap 130 about the appendage to thereby secure the appendage mount 100 to the appendage.

Under the condition that a reel and lace cable system is utilized as the fastening means 140, a spacing member 138 may be utilized on the underside of the appendage strap 130 to keep the cables in their proper respective positions within the reel and lace cable system. Indeed, the spacing member 138 may be configured with spaces and stops, with an individual cable being confined in one of the spaces between opposing stops, such that an individual cable cannot travel over a stop into an adjacent space to overlap a neighboring cable. This prevents unwanted binding of the cable due to impact from outside forces or objects.

Embodiments of the appendage mount 100 permit the device housing 60 to be coupled to the appendage of a user, such that a user may wear the device housing 60 on an arm or a leg for easy access to the personal electronic device 2 housed within the device housing 60. Indeed, because the appendage mount 100 is configured to permit the device housing 60 to rest face-up and securely on the user's appendage, the user may easily access and operate the features of the personal electronic device 2 within the device housing 60, as described in detail above. Further, the appendage mount 100 provides easy access to the personal electronic device through the opening of the housing lid 64 from the housing body 64. In this way, the user may remove the personal electronic device 2 from the device housing 60 without removing the device housing 60 from the appendage mount 100, when needed. Such versatility provides convenience, safety, and ease of use to the user of the personal electronic device 2, as described more fully above.

While this disclosure has been described in conjunction with the specific embodiments outlined above, it is evident that many alternatives, modifications and variations will be apparent to those skilled in the art. Accordingly, the preferred embodiments of the present disclosure as set forth above are intended to be illustrative, not limiting. Various changes may be made without departing from the spirit and scope of the present disclosure, as required by the following claims. The claims provide the scope of the coverage of the present disclosure and should not be limited to the specific examples provided herein.

What is claimed is:

1. A communication system for an electronic device, the system comprising:
a device housing having a housing body with a transparent surface, the housing body defining a cavity, the cavity being configured to house the electronic device therein such that a touchscreen of the electronic device is visible through the transparent surface;
a coupling member having a coupling plate and a coupling body, the coupling plate being configured to releasably couple to the housing body, the coupling plate and the coupling body being configured to pivot with respect to one another between a closed position and an open position; and
a communication port coupled to the housing body and configured to place the electronic device in electrical communication with an external electronic device,
wherein in the closed position the transparent surface is proximate the coupling body and in the open position the touchscreen is accessible.

2. The system of claim 1, wherein the device housing further comprises a housing lid that is configured to pivot between an unlatched position and a latched position, wherein in the unlatched position the housing lid provides access to the cavity and in the latched position the housing lid is configured to close the cavity.

3. The system of claim 1, further comprising a retaining member configured to functionally engage the coupling plate to retain the coupling plate and the coupling body in the closed position.

4. The system of claim 1, wherein the coupling body is configured to releasably couple to a user.

5. The system of claim 4, wherein the coupling body further comprises a plurality of prongs that are configured to releasably couple to PALS webbing in a MOLLE system worn by the user.

6. The system of claim 3, wherein the retaining member is configured to releasably couple to a user.

7. The system of claim 6, wherein the retaining member further comprises a plurality of prongs that are configured to releasably couple to PALS webbing in a MOLLE system worn by the user.

8. The system of claim 1, wherein the communication port further comprises a USB plug housed within a shield member, wherein the shield member is configured to shield the USB plug from EMI, and wherein the USB plug operatively engages the electronic device to establish connection between the electronic device and the external electronic device via a cable.

9. The system of claim 1, wherein the external electronic device is a power source.

10. The system of claim 1, wherein the external electronic device is a computer.

11. A protective cover for an electronic device, the protective cover comprising:
a housing body defining a cavity therein,
a transparent screen coupled to the housing body, the transparent screen providing visibility into the cavity;
a housing lid in functional communication with the housing body to provide access to the cavity and to seal the cavity; and
a communication port coupled to the housing body and configured to place the electronic device in electrical communication with an external electronic device via a cable.

12. The protective cover of claim 11, wherein the cavity is configured to house the electronic device, and wherein under the condition the electronic device is in the cavity a touchscreen display of the electronic device is visible through the transparent screen, the transparent screen being conductive to allow a user to operate the touchscreen display of the electronic device through the transparent screen.

13. The protective cover of claim 11, wherein the cavity is hermetically sealed, and wherein transparent screen, the housing lid, the communication port, and a control positioned on the housing body functionally couple only to the housing body to thus limit a number of component parts that must communicate with one another to create the hermetic seal of the cavity.

14. The protective cover of claim 11, wherein the housing body has a rigid unitary construction and under the condition the housing lid functionally engages the housing body, the cavity is hermetically sealed.

15. The protective cover of claim 11, wherein the communication port is a USB plug that operatively engages a corresponding USB port of the electronic device within the cavity.

16. The protective cover of claim 11, wherein the communication port further comprises a shield member, the shield member comprising metal and being configured to enclose the USB plug to shield the USB plug from emitting EMI.

17. The protective cover of claim 16, wherein the shield member further comprises foam positioned between the USB plug and the shield member on opposing sides of the USB plug to permit the USB plug to move in response to movement of the electronic device.

18. The protective cover of claim 17, wherein the foam is conductive on the side of the USB plug that has a standard metal shield and the foam is non-conductive on the opposing side of the USB plug.

19. The protective cover of claim 11, wherein the housing body further comprises surface features proximate the transparent screen, the surface features being configured on the housing body to correspond to a position of software buttons on the touchscreen of the device.

20. The protective cover of claim 11, wherein the housing body further comprises controls, the controls being positioned on an exterior of the housing body and configured to actuate buttons on the electronic device within the cavity, the controls being configured to provide a hermetical seal between the exterior surface of the housing body and the cavity.
